(19) United States
(12) Patent Application Publication
(10) Pub. No.: US 2020/0335402 A1
(43) Pub. Date: Oct. 22, 2020

(54) SEMICONDUCTOR DEVICE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Fei ZHOU, Shanghai (CN)

(21) Appl. No.: 16/851,645

(22) Filed: Apr. 17, 2020

(30) Foreign Application Priority Data
Apr. 18, 2019 (CN) 201910314464.2

(51) Int. Cl. H01L 21/8238; H01L 27/092; H01L 29/06; H01L 29/423; H01L 29/786; H01L 21/02; H01L 21/762; H01L 29/66

(52) U.S. Cl. CPC H01L 21/823821; H01L 29/66742; H01L 29/0673; H01L 29/0649; H01L 29/42392; H01L 29/78681; H01L 29/78684; H01L 29/78696; H01L 21/02603; H01L 21/02532; H01L 21/02546; H01L 21/76229; H01L 21/823878; H01L 29/66522; H01L 27/092

(57) ABSTRACT

Semiconductor devices and fabrication methods are provided. An exemplary fabrication method includes providing a substrate having a first region and a second region; sequentially forming a first sacrificial layer, a first semiconductor layer, a second sacrificial layer and a second semiconductor layer over the substrate; sequentially removing the second semiconductor layer, the second sacrificial layer, the first semiconductor layer, the first sacrificial layer over the second region of the substrate and a partial thickness of the substrate in the second region; sequentially forming a third sacrificial layer, a third semiconductor layer, a fourth sacrificial layer, and a fourth semiconductor layer over the second region of the substrate. A thickness of the third sacrificial layer is greater than a thickness of the first sacrificial layer, and a thickness of the fourth sacrificial layer is greater than a thickness of the second sacrificial layer.

### CROSS-REFERENCES TO RELATED APPLICATIONS

This application claims the priority of Chinese patent application No. 201910314464.2, filed on Apr. 18, 2019, the entirety of which is incorporated herein by reference.

### FIELD OF THE DISCLOSURE

The present disclosure generally relates to the field of semiconductor manufacturing technology and, more particularly, relates to semiconductor devices and fabrication methods.

### BACKGROUND

With the rapid development of the semiconductor manufacturing technologies, integrated circuits (ICs) are being developed toward higher component densities and higher integration level. As one of the basic components of ICs, semiconductor devices are widely used. A conventional planar device usually has a weak control on its channel current, and a short channel effect is easy to occur to have a leakage current issue. Thus, the electrical performance of the semiconductor devices is adversely affected.

To overcome the short channel effect of the semiconductor devices and suppress the leakage current, fin field-effect transistors (FinFETs) have been developed. FinFETs are a common type of multi-gate devices. The structure of an FinFET often includes a plurality of fins and an isolation layer on a surface of a substrate. The isolation layer covers portions of the sidewall surfaces of the fins, and the top surface of the isolation layer is lower than the top surfaces of the fins. The FinFET also includes a gate structure on the surface of the isolation layer by covering the top and sidewall surfaces of the fins, and source/drain regions in the fins at both sides of the gate structure.

With the ever-increasing demands placed on the device performance, a four-sided controlled gate-all-around structure has been developed. A semiconductor device having a gate-all-around structure has a special performance that effectively suppresses the short channel effect, and is expected by the semiconductor industry to continue to reduce the size of the device in accordance with the Moore's Law.

However, there is still a need to further improve the performance of the semiconductor device with a gate-all-around structure. The disclosed methods and semiconductor devices are directed to solve one or more problems set forth above and other problems in the art.

### BRIEF SUMMARY OF THE DISCLOSURE

One aspect of the present disclosure includes a method for forming a semiconductor device. The method may include providing a substrate having a first region and a second region; forming a first sacrificial layer on the substrate, a first semiconductor layer on the first sacrificial layer, a second sacrificial layer on the first semiconductor layer, and a second semiconductor layer on the second sacrificial layer; sequentially removing the second semiconductor layer over the second region, the second sacrificial layer over the second region, the first semiconductor layer over the second region, the first sacrificial layer over the second region and a partial thickness of the substrate in the second region; and forming a third sacrificial layer over the second region of the substrate, a third semiconductor layer on the third sacrificial layer, a fourth sacrificial layer on the third semiconductor layer, and a fourth semiconductor layer on the fourth sacrificial layer. The thickness of the third sacrificial layer is greater than the thickness of the first sacrificial layer; and the thickness of the fourth sacrificial layer is greater than the thickness of the second sacrificial layer. The method may also include etching the second semiconductor layer, the second sacrificial layer, the first semiconductor layer, and the first sacrificial layer over the first region of the substrate and a partial thickness of the substrate in the first region to form a first region fin; etching the fourth semiconductor layer, the fourth sacrificial layer, the third semiconductor layer, and the third sacrificial layer over the second region of the substrate and a partial thickness of the substrate in the second region to form a second region fin; forming a first trench in the first region fin by removing the first sacrificial layer in the first region fin; forming a second trench in the first region fin by removing the second sacrificial layer in the first region fin; forming a third trench in the second region fin by removing the third sacrificial layer in the second region; and forming a fourth trench in the second region fin by removing the fourth sacrificial layer in the second region fin.

Another aspect of the present disclosure includes a semiconductor device. The semiconductor structure may include a substrate having a first region and a second region; a first semiconductor layer above the first region of the substrate; a second semiconductor layer above the first semiconductor layer; a first trench between the substrate and the first semiconductor layer; a second trench between the first semiconductor layer and the second semiconductor layer;

a third semiconductor layer above the second region of the substrate; a fourth semiconductor layer above the third semiconductor layer; a third trench between the second region of the substrate and the third semiconductor layer; and a fourth trench between the third semiconductor layer and the fourth semiconductor layer. The size of the third trench is greater than the size of the first trench; and the size of the fourth trench is greater than the size of the second trench.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-3 illustrate structures corresponding to certain stages when forming a patterned structure;

FIGS. 4-9 illustrate structures corresponding to certain stages during an exemplary fabrication process of a semiconductor device consistent with various disclosed embodiments of the present disclosure;

FIGS. 10-11 illustrate structures corresponding to certain stages during another exemplary fabrication process of a semiconductor device consistent with various disclosed embodiments of the present disclosure; and

FIG. 12 illustrates an exemplary fabrication process of a semiconductor device consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

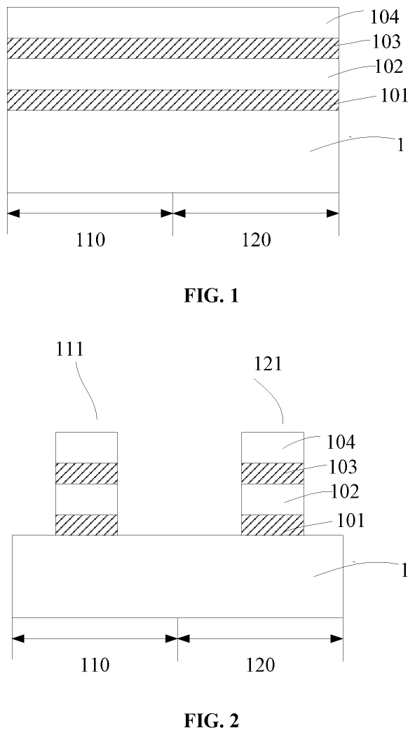

FIGS. 1-3 illustrate semiconductor structures corresponding to certain stages when forming a semiconductor device.

As shown in FIG. 1, at the beginning of the fabrication process, a substrate 1 is provided. The substrate 1 includes a first region 110 and a second region 120. A first sacrificial layer 101 is formed on the substrate 1. A first substrate layer 102 is formed on the first sacrificial layer 101. A second sacrificial layer 103 is formed on the first substrate layer 102. A second substrate layer 104 is formed on the second sacrificial layer 103.

Further, as shown in FIG. 2, the second substrate layer 104, the second sacrificial layer 103, the first substrate layer 102, and the first sacrificial layer 101 are sequentially etched, and the first region fin 111 is formed on the first region 110, and the second region fin 121 is formed on the second region 120.

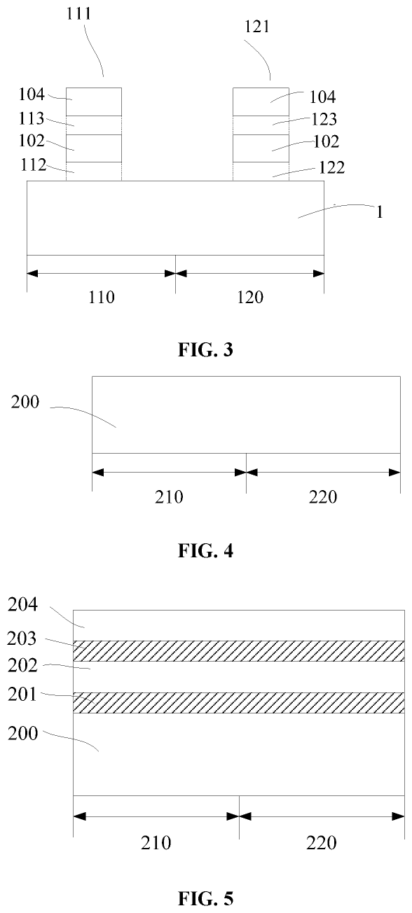

Further, as shown in FIG. 3, the first sacrificial layer 101 and the second sacrificial layer 103 in the first region fin 111 are removed, respectively, a first trench 112 is formed between the first region 110 of the substrate 1 and the first substrate layer 102; and a second trench 113 is formed between the first substrate layer 102 in the first region 110 and the second substrate layer 104 in the first region 110.

The first sacrificial layer 101 and the second sacrificial layer 103 in the second fin 121 are removed, respectively, a third trench 122 is formed between the second region 120 of the substrate 1 and the first substrate layer 102; and a fourth trench 123 is formed between the first substrate layer 102 in the second region 120 and the second substrate layer 104 in the second region 120.

In such a fabrication process, the size of the first trench 112, the size of the second trench 113, the size of the third trench 122, and the size of the fourth trench 123 are same. When filling the first trench 112, the second trench 113, the third trench 122, and the fourth trench 123 with a material layer, on the one hand, it is inconvenient to form a layer of material of different thicknesses in the first region 110 and the second region 120. On the other hand, when it is required to fill a substantially thick layer of material in the trench in the first region 110 or the trench in the second region 120, because the space provided by the trench is substantially small, when the material layer is filled, it is easy to have an issue that the material layer is only filled on the edge of the trench, and a bridging issue occurs. Accordingly, the performance of the semiconductor device is adversely affected.

The present disclosure provides a semiconductor device and a method for forming a semiconductor device. In the method for forming a semiconductor device, sacrificial layers of different thicknesses may be formed on the first region and the second region to occupy spaces first. When the sacrificial layers are subsequently removed, trenches of different sizes may be formed. Thus, using the trenches of different sizes may facilitate the formation of layers of materials of different thicknesses over the first region and the second region of the substrate. Further, when filling the material layers in the trenches, by using trenches of different sizes, the material layer desired to have a larger thickness may be filled in the trench with a larger size. Because the pressure in the trench may be small, the material layer may be sufficiently filled into the trench without being attached only to the edge of the trench to cause the bridging issue. Accordingly, the performance of the semiconductor device may be improved.

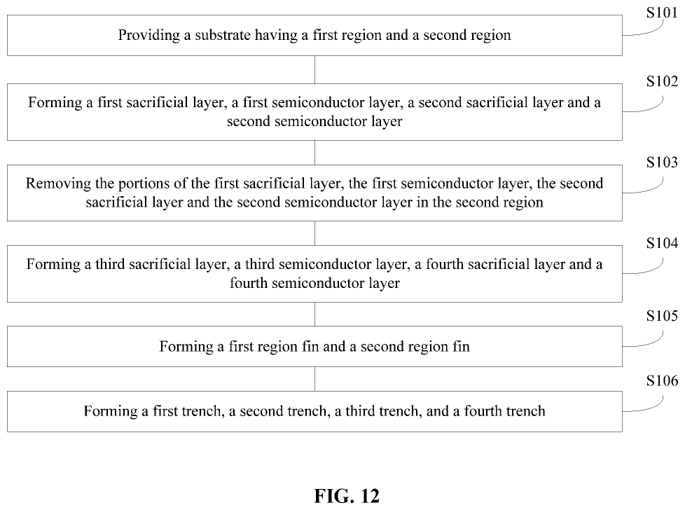

FIG. 12 illustrates an exemplary fabrication process of a semiconductor structure consistent with various disclosed embodiments of the present disclosure. FIGS. 4-9 illustrate semiconductor structures corresponding to certain stages during the exemplary fabrication process consistent with various disclosed embodiments of the present disclosure.

As shown in FIG. 12, at the beginning of the fabrication process, a substrate with certain structures is provided. FIG. 4 illustrates a corresponding semiconductor structure.

As shown in FIG. 4, a substrate 200 is provided. The substrate 200 may have a first region 210 and a second region 220.

In one embodiment, the substrate 200 is made of single crystal silicon. In some embodiments, the substrate 200 may be made of polysilicon or amorphous silicon. In other embodiments, the substrate 200 may be made of other semiconductor material, such as germanium, silicon germanium, or gallium arsenide, etc.

In one embodiment, the first region 210 is an NMOS region, and the second region 220 is a PMOS region. In some embodiments, the first region may be a PMOS region, and the second region may be an NMOS region.

Returning to FIG. 12, after providing the substrate, a first sacrificial layer, a first semiconductor layer, a second sacrificial layer and a second semiconductor layer may be formed (S102). FIG. 5 illustrates a corresponding semiconductor structure.

As shown in FIG. 5, a first sacrificial layer 201, a first semiconductor layer 202, a second sacrificial layer 203, and a second semiconductor layer 204 may be sequentially formed on the substrate 200.

In one embodiment, the first sacrificial layer 201 is made of silicon germanium (SiGe). In some embodiments, the material of the first sacrificial layer 201 may also be one of silicon, germanium, or gallium arsenide, etc.

In one embodiment, the first semiconductor layer 202 is made of silicon (Si). In some embodiments, the material of the first semiconductor layer 202 may also be one or more of silicon germanium, silicon carbide, gallium arsenide or indium arsenide, etc.

In one embodiment, the second sacrificial layer 203 is made of silicon germanium (SiGe). In some embodiments, the material of the second sacrificial layer 203 may also be one or more of silicon, germanium, or gallium arsenide, etc.

In one embodiment, the second semiconductor layer 204 is made of silicon (Si). In some embodiments, the material of the second semiconductor layer 204 may also be one or more of silicon germanium, silicon carbide, gallium arsenide, or indium arsenide, etc.

In one embodiment, the first semiconductor layer 202 and the second semiconductor layer 204 is made of a same material. In some embodiments, the materials of the first semiconductor layer 202 and the second semiconductor layer 204 may be different.

In one embodiment, the first sacrificial layer 201 and the second sacrificial layer 203 may be made of a same material. In some embodiments, the materials of the first sacrificial layer 201 and the second sacrificial layer 203 may be different.

In one embodiment, the thickness of the first semiconductor layer 202 may be same as the thickness of the second semiconductor layer 204. In some embodiments, the thickness of the first semiconductor layer 202 and the thickness of the second semiconductor layer 204 may be different.

In one embodiment, the thicknesses of the first sacrificial layer 201 and the second sacrificial layer 203 may be same. In some embodiments, the thicknesses of the first sacrificial layer 201 and the second sacrificial layer 203 may be different.

In one embodiment, the first sacrificial layer 201, the first semiconductor layer 202, the second sacrificial layer 203, and the second semiconductor layer 204 are formed by an epitaxial growth process.

In one embodiment, the parameters for forming the first sacrificial layer 201 and the second sacrificial layer 203 may include a following combination.

The reaction gas may include hydrogen (H₂), hydrogen chloride (HCl) gas, DCS gas, GeH₄ gas, and B₂H₆ gas. The flow rate of the hydrogen (H₂) may be in range of approximately 10 sccm to 3000 sccm. The flow rate of the hydrogen chloride (HCl) gas may be in a range of approximately 10 sccm to 200 sccm. The flow rate of the DCS gas may be in a range of approximately 20 sccm to 2000 sccm. The flow rate of the GeH₄ may be in a range of approximately 10 sccm-500 sccm. The flow rate of the B₂H₆ gas may be in a range of approximately 5 sccm-600 sccm. The temperature may be in range of approximately 600° C.-850° C. The pressure may be in a range of approximately 8 mTorr-300 mTorr. The time may be in a range of approximately 10 min˜1 h.

In one embodiment, the process parameters for forming the first semiconductor layer 202 and the second semiconductor layer 204 may include a following combination.

The reaction gases may include hydrogen (H₂), hydrogen chloride (HCl) gas, DCS gas, SiH₄ gas, and B₂H₆ gas. The flow rate of the hydrogen (H₂) may be in a range of approximately 10 sccm to 3000 sccm. The flow rate of the hydrogen chloride (HCl) gas may be in a range of approximately 10 sccm to 250 sccm. The flow rate of the DCS gas may be in a range of approximately 20 sccm to 2500 sccm. The flow rate of the SiH₄ gas may be in a range of approximately 10 sccm to 700 sccm. The flow rate of the B₂H₆ gas may be in a range of approximately 5 sccm to 400 sccm. The pressure may be in a range of approximately 8 mTorr to 300 mTorr. The temperature may be in a range of approximately between 600° C. to 850° C.

The sacrificial layers and the semiconductor layers formed by the epitaxial growth may be P-type and N-type materials with substantially high conductivities. Further, the integrity of the obtained sacrificial layers and semiconductor layers may be as desired; and the quality of semiconductor device may be as desired.

In some embodiments, an ion doping process or a chemical vapor deposition (CVD) process may be used to form the first sacrificial layer 201 on the substrate 200, the first semiconductor layer 201 on the first sacrificial layer 201, the second sacrificial layer 203 on the first semiconductor layer 202 and the second semiconductor layer 204 on the second sacrificial layer 203.

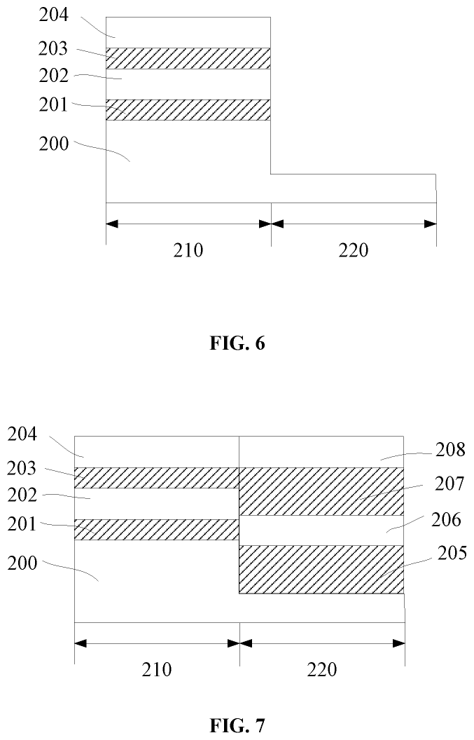

Returning to FIG. 12, after forming the first sacrificial layer, the first semiconductor layer, the second sacrificial layer and the second semiconductor layer, the portions of the first sacrificial layer, the first semiconductor layer, the second sacrificial layer and the second semiconductor layer in the second region may be removed (S103). FIG. 6 illustrates a corresponding semiconductor structure.

As shown in FIG. 6, the second semiconductor layer 204 over the second region 220, the second sacrificial layer 203 over the second region 220, the first semiconductor layer 202 over the second region 220, the first sacrificial layer 201 over the second region 220, and a partial thickness of the substrate 200 in the second region 220 may be removed.

In one embodiment, the process for removing the second sacrificial layer 203 and the first sacrificial layer 201 in the second region 220 may be a wet etching process. The etching solution of the wet etching process may have a desired etching selectivity between silicon and silicon germanium such that it may ensure that the morphology of silicon is not affected while removing silicon germanium.

In one embodiment, the parameters of the wet etching process may include a following combination. The etching solution may be a HCl solution. The temperature may be in a range of approximately 25° C. to 300° C. The volume percentage of HCl in the HCl solution may be in a range of approximately 20% to 90%.

In one embodiment, the process for removing the second semiconductor layer 204, the first semiconductor layer 202, and the partial thickness of the substrate 200 in the second region may be a wet etching process. The etching solution of the wet etching process may have a desired etching selectivity between silicon and silicon germanium such that it may ensure that the morphology of silicon germanium is not affected while removing silicon.

In one embodiment, the parameters of the wet etching process may include a following combination. The etching solution may be a tetramethylammonium hydroxide solution. The temperature may be in a range of approximately 20° C. to 80° C. The volume percentage of tetramethylammonium hydroxide in the tetramethylammonium hydroxide solution may be in a range of approximately 10%-80%.

Returning to FIG. 12, after removing the second semiconductor layer, the second sacrificial layer, the first semiconductor layer, the first sacrificial layer, and the partial thickness of the substrate in the second region, a third sacrificial layer, a third semiconductor layer, a fourth sacrificial layer and a fourth semiconductor layer may be formed (S104). FIG. 7 illustrates a corresponding semiconductor structure.

As shown in FIG. 7, a third sacrificial layer 205 may be formed on the substrate 200 in the second region 200; a third semiconductor layer 206 may be formed on the third sacrificial layer 205; a fourth sacrificial layer 207 may be formed on the third semiconductor layer 206; and a fourth semiconductor layer 208 may be formed on the fourth sacrificial layer 207.

In one embodiment, the third sacrificial layer 205 is made of silicon germanium (SiGe). In some embodiments, the material of the third sacrificial layer 205 may also be one or more of silicon, germanium or gallium arsenide, etc.

In one embodiment, the third semiconductor layer 206 is made of silicon (Si). In some embodiments, the third semiconductor layer 206 may also be made of one or more of silicon germanium, silicon carbide, gallium arsenide, or indium arsenide, etc.

In one embodiment, the fourth sacrificial layer 207 is made of silicon germanium (SiGe). In some embodiments, the material of the fourth sacrificial layer 207 may also be one or more of silicon, germanium, or gallium arsenide, etc.

In one embodiment, the fourth semiconductor layer 208 is made of silicon (Si). In some embodiments, the material of the fourth semiconductor layer 208 may also be silicon germanium, silicon carbide, gallium arsenide, or indium arsenide, etc.

In one embodiment, the materials of the third sacrificial layer 205 and the fourth sacrificial layer 207 are same. In some embodiments, the materials of the third sacrificial layer 205 and the fourth sacrificial layer 207 may be different.

In one embodiment, the materials of the third semiconductor layer 206 and the fourth semiconductor layer 208 are same. In some embodiments, the materials of the third semiconductor layer 206 and the fourth semiconductor layer 208 may be different.

In one embodiment, an epitaxial growth process may be used to form the third sacrificial layer 205 on the substrate 200 in the second region 220, the third semiconductor layer 206 on the third sacrificial layer 205, the fourth sacrificial layer 207 on the third semiconductor layer 206 and the fourth semiconductor layer 208 on the fourth sacrificial layer 207.

In some embodiments, the third sacrificial layer 205, the third semiconductor layer 206, the fourth sacrificial layer 207, and the fourth semiconductor layer 208 may also be formed by a chemical vapor deposition (CVD) process or an atomic layer deposition (ALD) process, or an ion doping process, etc.

In one embodiment, the third semiconductor layer 206 and the fourth semiconductor layer 208 may formed by same process parameters as those used for forming the first semiconductor layer 202 and the second semiconductor layer 204. In some embodiments, the third semiconductor layer 206 and the fourth semiconductor layer 208 may be formed by different process parameters.

In one embodiment, the process parameters for forming the third sacrificial layer 205 and the fourth sacrificial layer 207 may include a following combination.

The reaction gases may include hydrogen (H₂) gas, hydrogen chloride (HCl) gas, DCS gas, GeH₄ gas, and B₂H₆ gas, etc. The flow rate of the hydrogen (H₂) gas may be in a range of approximately 10 sccm to 3000 sccm. The flow rate of the hydrogen chloride (HCl) gas may be in a range of approximately 10 sccm to 200 sccm. The flow rate of the DCS gas may be in a range of approximately 20 sccm to 2000 sccm. The flow rate of the GeH₄ gas may be in a range of approximately 10 sccm to 500 sccm. The flow rate of the B₂H₆ gas may be in a range of approximately 5 sccm to 600 sccm. The temperature may be in a range of approximately 600° C. to 850° C. The pressure may be in a range of approximately 8 mTorr to 300 mTorr. The reaction time may be in a range of approximately 10 mins to 1 h.

In one embodiment, the thickness of the third sacrificial layer 205 may be same as the thickness of the fourth sacrificial layer 207. In some embodiments, the thickness of the third sacrificial layer 205 and the thickness of the fourth sacrificial layer 207 may be different.

In one embodiment, the thickness of the third semiconductor layer 206 may be same as the thickness of the fourth semiconductor layer 208. In some embodiments, the thickness of the third semiconductor layer 206 and the thickness of the fourth semiconductor 208 may be different.

In one embodiment, the thickness of the third sacrificial layer 205 may be greater than the thickness of the first sacrificial layer 201; and the thickness of the fourth sacrificial layer 207 may be greater than the thickness of the second sacrificial layer 203. Such an arrangement may enable to form larger trenches in the second region 220 when the sacrificial layers are subsequently removed to form the trenches.

In one embodiment, the thickness of the first semiconductor layer 202 may be same as the thickness of the third semiconductor layer 206. In some embodiments, the thickness of the first semiconductor layer 202 and the thickness of the third semiconductor layer 206 may be different.

In one embodiment, the top surface of the second semiconductor layer 204 may level with the top surface of the fourth semiconductor layer 208. In some embodiments, the top surface of the second semiconductor layer 204 and the top surface of the fourth semiconductor layer 208 may be at different levels.

In one embodiment, the top surface of the second sacrificial layer 203 may level with the top surface of the fourth sacrificial layer 207. In some embodiments, the top surface of the second sacrificial layer 203 and the top surface of the fourth sacrificial layer 207 may be at different levels.

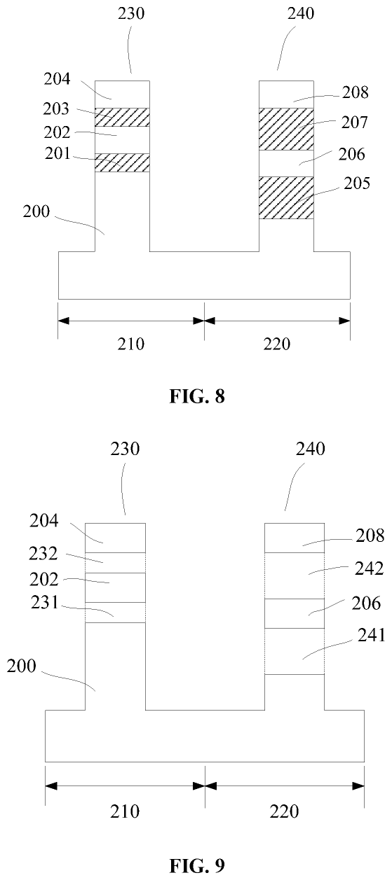

Returning to FIG. 12, after forming the third sacrificial layer, the third semiconductor layer, the fourth sacrificial layer and the fourth semiconductor layer, a first region fin and a second region fin may be formed (S105). FIG. 8 illustrates a corresponding semiconductor structure.

As shown in FIG. 8, a first region fin 230 may be formed by etching the second semiconductor layer 204 over the first region 210, the second sacrificial layer 203 over the first region 210, the first semiconductor layer 202 over the first region 210, the first sacrificial layer 201 over the first region 210, and a partial thickness of the substrate 200 in the first region 210. Further, a second region fin 240 may be formed by etching the fourth semiconductor layer 208 over the second region 220, the fourth sacrificial layer 207 over the second region 220, the third semiconductor layer 206 over the second region 220, and the third sacrificial layer 205 over the second region 220 and a partial thickness of the substrate 200 in the second region 220. In one embodiment, the first region fin 230 and the second region fin 240 may be formed simultaneously.

In one embodiment, the parameters for forming the first region fin 230 by the etching process may include a following combination. The etching gases may include CF₄ gas and hydrogen gas (H₂). The flow rate of the CF₄ gas may be in a range of approximately 10 sccm to 300 sccm. The flow rate of the hydrogen gas (H₂) may be in a range of approximately 20 sccm to 500 sccm. The etching time may be in a range of approximately 5 s to 500 s.

In one embodiment, the process parameters for forming the second region fin 240 may include a following combination. The etching gas may include a mixture of oxygen (O₂), CH₃F gas, and helium (He). The flow rate of the oxygen (O₂) may be in a range of approximately 5 sccm-9005 sccm. The flow rate of the CH₃F gas may be in a range of approximately 60 sccm-8000 sccm. The flow rate of helium (He) may be in a range of approximately 60 sccm-2000 sccm. The reaction time may be in range of approximately 50 s-10000 s.

Returning to FIG. 12, after forming the first region fin and the region second fin, a first trench, a second trench, a third trench, and a fourth trench may be formed (S106). FIG. 9 illustrates a corresponding semiconductor structure.

As shown in FIG. 9, a first trench 231, a second trench 232, a third trench 241, and a fourth trench 242 may be formed.

The first trench 231 may be formed in the first region fin 230 by removing the first sacrificial layer 201 in the first region fin 230.

At the same time, the second trench 232 may be formed in the first region fin 230 by removing the second sacrificial layer 203 in the first region fin 230.

At the same time, the third trench 241 may be formed in the second region fin 240 by removing the third sacrificial layer 205 in the second region fin 240.

At the same time, the fourth trench 242 may be formed in the second region fin 240 by removing the fourth sacrificial layer 207 in the second region fin 240.

In one embodiment, the thickness of the third sacrificial layer 205 may be greater than the thickness of the first sacrificial layer 201; and the thickness of the fourth sacrificial layer 207 may be greater than the thickness of the second sacrificial layer 203. Thus, the third trench 241 and the fourth trench 242 may be greater than the first trench 231 and the second trench 232. By using the thicker third sacrificial layer 205 and the thicker fourth sacrificial layer 207 to occupy larger spaces first, after removing the first sacrificial layer 201, the second sacrificial layer 203, the third sacrificial layer 205, and the fourth sacrificial layer 207, the third trench 241 and the fourth trench 242 may be ensured to be greater than the first trench 231 and the second trench 232. Thus, a thicker material layer may be easily formed in the third trench 241 and the fourth trench 242, and a thinner material layer may be formed in the first trench 231 and the second trench 232. Accordingly, the needs of different functional regions having different thicknesses of material layers may be met. At the same time, because the third trench 241 and the fourth trench 242 are larger, when forming a thicker material layer, it is convenient for the material layer to be uniformly filled in the trenches, and the issue that the material layer can only adhere to the sidewalls of the trenches caused by the high gas pressure in the trenches with a smaller size may be avoided. Accordingly, the bridging problem may be avoided.

In one embodiment, the first sacrificial layer 201 in the first region fin 230, the second sacrificial layer 203 in the first region fin 230, the third sacrificial layer 205 in the second region fin 240 and the fourth sacrificial layer 207 in the second region fin 240 may be removed by a mixed gas of water vapor and hydrogen chloride. The volume ratio of water vapor and hydrogen chloride may be in a range of approximately 20%-90%; and the temperature may be in range of approximately 25° C.-300 ° C.

After forming the first trench 231, the second trench 232, the third trench 241, and the fourth trench 242, a first material layer may be formed around the first semiconductor layer 202 in the first region fin 230. Simultaneously, a second material layer may be formed around the second semiconductor layer 204 in the first region fin 230, a third material layer may be formed around the third semiconductor layer 206 in the second region fin 240; and a fourth material layer may be formed around the fourth semiconductor layer 208 in the second region fin 240.

The first material layer, the second material layer, the third material layer and the fourth material layer may be single layer structures, or multiple layer structures; and may include gate layers and/or work function layers, etc. The first material layer, the second material layer, the third material layer and fourth material layer may be used to form gate structures.

The formation methods and materials of the first material layer, the second material layer, the third material layer, and the fourth material layer may be same. Taking the formation of the third material layer as an example, the formation step may include forming an interface layer (IL) surrounding the third semiconductor layer 206 in the third trench 241 and the fourth trench 242; forming a high-K metal layer on the interface layer (IL); and forming a work function layer on the high-K metal layer.

Accordingly, the present disclosure also provides a semiconductor device. FIG. 9 illustrates an exemplary semiconductor device consistent with various disclosed embodiments of the present disclosure.

As shown in FIG. 9, the semiconductor device may include a substrate 200 having a first region 210 and a second region 220, and a first semiconductor layer 202 over the first region 210 of the substrate 200, and a second semiconductor layer 204 over the first semiconductor layer 202. Further, the semiconductor device may include a first trench 231 between the substrate 200 in the first region 210 and the first semiconductor layer 202, a second trench 232 between the first semiconductor layer 202 and the second semiconductor layer 204. Further, the semiconductor device may include a third semiconductor layer 206 over the second region 220 of the substrate 200, and a fourth semiconductor layer 208 over the third semiconductor layer 206. Further, the semiconductor device may include a third trench 241 between the substrate 200 in the second region 220 and the third semiconductor layer 206; and a fourth trench 242 between the third semiconductor layer 206 and the fourth semiconductor layer 208.

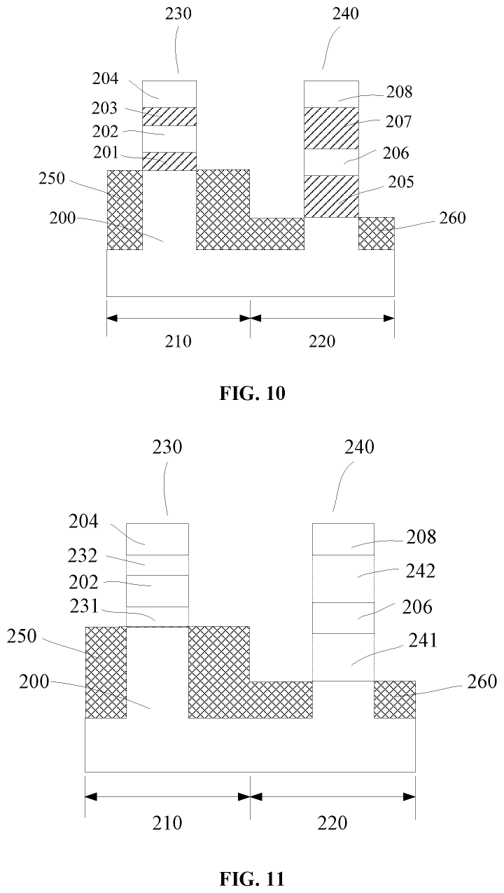

FIGS. 10-11 illustrate structures corresponding to certain stages during another exemplary fabrication process of a semiconductor device consistent with various disclosed embodiments of the present disclosure. The steps from providing the substrate 200 to forming the first region fin 230 and the second region fin 240 may be same as those of the previously described embodiments and the detailed may be referred to FIGS. 4-8.

Referring to FIG. 10, the difference between the process and the previously described process may include that, after forming the first region fin 230 and the second region fin 240 and before removing the first sacrificial layer 201 in the first region fin 230, an oxide layer may be formed on the substrate 200.

After forming the oxide layer, the steps of removing the first sacrificial layer 201, the second sacrificial layer 203, the third sacrificial layer 205, and the fourth sacrificial layer 207 may be same as those in the previously described embodiments.

As shown FIG. 10, after forming the first region fin 230 and the second region fin 240, a first oxide layer 250 may be formed on the substrate 200 in the first region 210. At the same time, a second oxide layer 260 may be formed on the substrate 200 in the second region 220.

In one embodiment, the first oxide layer 250 and the second oxide layer 260 may be formed on the substrate 200. In some embodiments, the first oxide layer and the second oxide layer may not be formed on the substrate.

In one embodiment, a top surface of the first oxide layer 250 may level with a bottom surface of the first sacrificial layer 201.

In one embodiment, a top surface of the second oxide layer 260 may level with a bottom surface of the third sacrificial layer 205.

In one embodiment, there may be a height difference between the first oxide layer 250 and the second oxide layer 260. Such a configuration may protect the portion of the substrate 200 covered by the first oxide layer 250 and the second oxide layer 260; and may prevent the damage to the substrate surface in the subsequent processes. Thus, the effect to the performance of the semiconductor device may be avoided.

In one embodiment, the first oxide layer 250 and the second oxide layer 260 may be made of a same material, and may be both made of silicon oxide. In some embodiments, the first oxide layer and the second oxide layer may be made of silicon oxynitride, silicon nitride, silicon oxycarbide, silicon carbonitride, or silicon oxycarbonitride, etc.

In one embodiment, the first oxide layer 250 and the second oxide layer 260 may be used as an etching stop layer in the subsequent etching processes to protect the integrity of the surface of the substrate surrounded and covered by the first oxide layer 250 and the second oxide layer 260 to ensure the quality of the formed semiconductor device.

Further, as shown in FIG. 11, after forming the first oxide layer 250 and the second oxide layer 260, the first sacrificial layer 201, the second sacrificial layer 203, the third sacrificial layer 205, and the fourth sacrificial layer 207 may be removed to form the first trench 231, the second trench 232, the third trench 241, and the fourth trench 242.

Accordingly, the present disclosure also provides another semiconductor device. FIG. 11 illustrates another exemplary semiconductor device consistent with various disclosed embodiments of the present disclosure.

As shown in FIG. 11, the semiconductor device may include a substrate 200 having a first region 210 and a second region 220, and a first oxide layer 250 over the first region 210 of the substrate 200. The semiconductor structure may also include a first semiconductor layer 202 over the first region 210 of the substrate 200; a second semiconductor layer 204 above the first semiconductor layer 202; a first trench 231 between the substrate 200 and the first semiconductor layer 202; a second trench 232 between the first semiconductor layer 202 and the second semiconductor layer 204. Further, the semiconductor device may include a second oxide layer 260 over the second region 220of the substrate 200; a third semiconductor layer 206 over the second region 220 of the substrate 200; a fourth semiconductor layer 208 over the third semiconductor layer 206; a third trench 241 between the substrate 200 and the third semiconductor layer 206; and a fourth trench 242 between the third semiconductor layer 206 and the fourth semiconductor layer 208. The detailed structures and intermediate structures are described above with respect to the fabrication processes.

The technical solutions of the present disclosure may have at least the following beneficial effects.

Because the thickness of the third sacrificial layer may be greater than the thickness of the first sacrificial layer and the thickness of the fourth sacrificial layer may be greater than the thickness of the second sacrificial layer, the third trench formed by the removing third sacrificial layer may be greater than the first trench formed by removing the first sacrificial layer, and the fourth trench formed by removing the fourth sacrificial layer may be greater than the second trench formed by removing the second sacrificial layer. When filling material layer in the first trench, the second trench, the third trench and the fourth trench, material layers with different thicknesses may be formed over the first region and the second region respectively. On the other hand, when filling the material layer of a larger thickness in the third trench and the fourth trench of a larger size, because the third trench and the fourth trench may provide substantially large spaces, the pressure inside the third trench and the fourth trench may be substantially small. Accordingly, when filling the material layer in the third trench and the fourth trench, the edge issue at the edges of the third trench and the fourth trench caused by the adhesion of the material layer at the edges of the third trench and the fourth trench may be avoided. Further, voids may not be formed inside the material layer and the quality of the material layer may be ensured. Accordingly, the performance of the semiconductor device may be enhanced.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

What is claimed is:

1. A method for fabricating a semiconductor device, comprising:
providing a substrate having a first region and a second region;
forming a first sacrificial layer on the substrate, a first semiconductor layer on the first sacrificial layer, a second sacrificial layer on the first semiconductor layer, and a second semiconductor layer on the second sacrificial layer;
sequentially removing the second semiconductor layer over the second region of the substrate, the second sacrificial layer over the second region of substrate, the first semiconductor layer over the second region of the substrate, the first sacrificial layer over the second region of the substrate and a partial thickness of the substrate in the second region;
forming a third sacrificial layer over the second region of the substrate, a third semiconductor layer on the third sacrificial layer, a fourth sacrificial layer on the third semiconductor layer, and a fourth semiconductor layer on the fourth sacrificial layer, wherein a thickness of the third sacrificial layer is greater than a thickness of the first sacrificial layer and a thickness of the fourth sacrificial layer is greater than a thickness of the second sacrificial layer;
etching the second semiconductor layer, the second sacrificial layer, the first semiconductor layer, and the first sacrificial layer over the first region of the substrate and a partial thickness of the substrate in the first region to form a first region fin;
etching the fourth semiconductor layer, the fourth sacrificial layer, the third semiconductor layer, and the third sacrificial layer over the second region of the substrate and a partial thickness of the substrate in the second region to form a second region fin;
forming a first trench in the first region fin by removing the first sacrificial layer over the first region fin of the substrate;
forming a second trench in the first region fin by removing the second sacrificial layer over the first region fin of the substrate;
forming a third trench in the second region fin by removing the third sacrificial layer over the second region of the substrate; and
forming a fourth trench in the second region fin by removing the fourth sacrificial layer over the second region fin of the substrate.

2. The method according to claim 1, wherein:
the first region is one of an NMOS region and a PMOS region; and
the second region is another one of the NMOS region and the PMOS region.

3. The method according to claim 1, wherein:
the first sacrificial layer, the first semiconductor layer, the second sacrificial and the second semiconductor layer are formed by an epitaxial growth process.

4. The method according to claim 1, wherein:
the third sacrificial layer over the second region of the substrate, the third semiconductor layer on the third sacrificial layer, the fourth sacrificial layer on the third semiconductor layer, and the fourth semiconductor layer on the fourth sacrificial layer are formed by an epitaxial growth process.

5. The method according to claim 1, wherein:
the first semiconductor layer is made of one or more of silicon, germanium, silicon germanium, or gallium arsenide.

6. The method according to claim 1, wherein:
the second semiconductor layer is made of one or more of silicon, germanium, silicon germanium, or gallium arsenide.

7. The method according to claim 1, wherein:
the third semiconductor layer is made of one or more of silicon, germanium, silicon germanium, or gallium arsenide.

8. The method according to claim 1, wherein:
the fourth semiconductor layer is made of one or more of silicon, germanium, silicon germanium, or gallium arsenide.

9. The method according to claim 1, wherein:
the first sacrificial layer is made of one or more of silicon, silicon germanium, silicon carbide, gallium arsenide, or indium gallium arsenide.

10. The method according to claim 1, wherein:
the second sacrificial layer is made of one or more of silicon, silicon germanium, silicon carbide, gallium arsenide, or indium gallium arsenide.

11. The method according to claim 1, wherein:
the third sacrificial layer is made of one or more of silicon, silicon germanium, silicon carbide, gallium arsenide, or indium gallium arsenide.

12. The method according to claim 1, wherein:
the fourth sacrificial layer is made of one or more of silicon, silicon germanium, silicon carbide, gallium arsenide, or indium gallium arsenide.

13. The method according to claim 1, after forming the first region fin and the second region fin and before removing the first sacrificial layer over the first region of the substrate, further comprising:
forming a first oxide layer over the first region of the substrate in and a second oxide layer over the second region of the substrate,
wherein:
a top surface of the first oxide layer levels with a bottom surface of the first sacrificial layer and a top surface of the second oxide layer levels with a bottom surface of the third sacrificial layer.

14. A semiconductor device, comprising:
a substrate having a first region and a second region;
a first semiconductor layer over the first region of the substrate;
a second semiconductor layer over the first semiconductor layer;
a first trench between the substrate and the first semiconductor layer;
a second trench between the first semiconductor layer and the second semiconductor layer;
a third semiconductor layer over the second region of the substrate;
a fourth semiconductor layer over the third semiconductor layer;
a third trench between the second region of the substrate and the third semiconductor layer; and
a fourth trench between the third semiconductor layer and the fourth semiconductor layer,
wherein:
a size of the third trench is greater than a size of the first trench; and
a size of the fourth trench is greater than a size of the second trench.

15. The semiconductor device according to claim 14, further comprising:
a first oxide layer over the first region of the substrate; and
a second oxide layer over the second region of the substrate.

16. The semiconductor device according to claim 14, wherein:
the first semiconductor layer is made of one or more of silicon, germanium, silicon germanium, or gallium arsenide.

17. The semiconductor device according to claim 14, wherein:
the second semiconductor layer is made of one or more of silicon, germanium, silicon germanium, or gallium arsenide.

18. The semiconductor device according to claim 14, wherein:
the third semiconductor layer is made of one or more of silicon, germanium, silicon germanium, or gallium arsenide.

19. The semiconductor device according to claim 14, wherein:
the fourth semiconductor layer is made of one or more of silicon, germanium, silicon germanium or gallium arsenide.

20. The semiconductor device according to claim 14, further comprising:
a first material layer around the first semiconductor layer in the first region fin;
a second material layer around the second semiconductor layer in the first region fin;
a third material layer around the third semiconductor layer in the second region fin; and
a fourth material layer around the fourth semiconductor layer in the second region fin.
